(19) United States
(12) Patent Application Publication
(10) Pub. No.: US 2025/0320603 A1
(43) Pub. Date: Oct. 16, 2025

(54) METHODS FOR IMPROVING THROUGHPUT AND GAPFILL QUALITY FOR METAL DEPOSITION

(71) Applicant: Applied Materials, Inc., Santa Clara, CA (US)

(72) Inventors: Tsung-Han Yang, San Jose, CA (US); Zhen Liu, Santa Clara, CA (US); Tejas Umesh Ulavi, Fremont, CA (US); Gayathri Sangadala, Sunnyvale, CA (US); Xingyao Gao, Santa Clara, CA (US); Rongjun Wang, Dublin, CA (US); Xianmin Tang, San Jose, CA (US)

(73) Assignee: Applied Materials, Inc., Santa Clara, CA (US)

(21) Appl. No.: 18/636,461

(22) Filed: Apr. 16, 2024

(51) Int. Cl. C23C 16/455; C23C 16/505; C23C 16/52

(52) U.S. Cl. CPC C23C 16/45538; C23C 16/45553; C23C 16/505; C23C 16/52

(57) ABSTRACT

A metal deposition method including exposing a substrate surface having at least one feature thereon to one or more deposition cycle, each deposition cycle including a metal precursor exposure portion and a reducing agent exposure portion, the metal precursor exposure portion including a flow of a metal precursor and a pulsed low-power RF plasma having a pulsed RF power of 100 W or less, the reducing agent exposure portion including a flow of a reducing agent and a high-power plasma having an RF power of 300 W or higher.

### TECHNICAL FIELD

Embodiments of the disclosure generally relate to electronic devices and methods of forming electronic devices. Embodiments of the disclosure relate to plasma-enhanced deposition of metals to form high-quality gapfills, including high-quality molybdenum gapfills.

### BACKGROUND

The miniaturization of semiconductor circuit elements has reached a point where feature sizes of 45 nm, 22 nm, 28 nm and even 20 nm are fabricated on a commercial scale. The advancing complexity of advanced microelectronic devices is placing stringent demands on currently used deposition techniques. As the dimensions continue to get smaller, new challenges arise for process steps like filling a gap between circuit elements with a variety of materials.

As the width between the elements continues to shrink, the gap between them often gets taller and narrower, making the gap more difficult to fill without the gapfill material getting stuck to create voids and weak seams. Conventional plasma-enhanced deposition techniques (e.g., PECVD, PEALD) often experience an overgrowth of material at the top of the gap before it has been completely filled. This is due to the inability of the plasma to penetrate into the deeper parts of the trench. The result is a pinching off of the trench from the top, which forms a void at the bottom of the trench. Another disadvantage with conventional CVD is the formation of seams, where a seam is a gap that forms in the feature between, but not necessarily in the middle of, the sidewalls of the feature. Thus, conventional CVD methods can create a void or seam in the gap where the depositing material has been prematurely cut off by the overgrowth.

Molybdenum and molybdenum-based films have attractive material and conductive properties. These films have been proposed and tested for applications from front-end to back-end parts of semiconductor and microelectronic devices. Molybdenum films may be used as low resistivity electrical connections in the form of vertical interconnects and/or horizontal interconnects through which current flows, as vias between adjacent metal layers, and as contacts between a first metal layer and the devices on a substrate.

At present, conventional methods of depositing molybdenum films utilize plasma-enhanced atomic layer deposition (PEALD). In PEALD, in a first step, gas-phase molybdenum-containing precursors are used to deposit molybdenum one layer at a time. In a second step, a reducing agent is flowed through the processing chamber in the presence of a plasma to reduce the molybdenum film to Mo(0) at a lower temperature than would be required using thermal ALD.

A disadvantage of conventional PEALD for metal gapfill is that they may have low throughput, in some cases having a throughput of only about 2 wafers per hour, depending on factors such as the wafer size. To increase the throughput, a plasma can be used in the chamber at the same time as flowing the gas-phase molybdenum precursor, as in plasma-enhanced chemical vapor deposition (PECVD). However, while PECVD increases the deposition rate of the molybdenum film, the deposited molybdenum does not fully penetrate into trenches of the substrate, leading to poor gapfill properties and the creation of seams or voids in the trenches.

Accordingly, there is an ongoing need for methods to deposit metal gapfills with high throughput while also maintaining high quality of the gapfills without voids or seams.

### SUMMARY

One or more embodiments of the present disclosure are directed to a metal deposition method including: exposing a substrate surface having at least one feature thereon to one or more deposition cycle. Each deposition cycle includes a metal precursor exposure portion and a reducing agent exposure portion. The metal precursor exposure portion includes a flow of a metal precursor and a pulsed low-power RF plasma having a pulsed RF power of 100 W or less. The reducing agent exposure portion includes a flow of a reducing agent and a high-power plasma having an RF power of 300 W or higher.

Additional embodiments of the disclosure are directed to a molybdenum deposition method including: performing a deposition cycle on a semiconductor substrate surface, and repeating the deposition cycle until the molybdenum film completely fills one or more features on the semiconductor substrate surface. Each deposition cycle includes: exposing the semiconductor substrate surface to a molybdenum precursor and a pulsed low-power RF plasma to form a molybdenum film on the semiconductor substrate surface, the pulsed low-power RF plasma having an RF power of 100 W or less and a pulse frequency of from 50 Hz to 500 Hz, and exposing the semiconductor substrate surface to a high-power plasma in the absence of the molybdenum precursor, the high-power plasma having a power of 300 W or greater.

Further embodiments of the disclosure are directed to a molybdenum deposition method including: exposing a substrate surface having at least one feature thereon to one or more deposition cycle. Each deposition cycle includes a molybdenum precursor exposure portion and a reducing agent exposure portion. The molybdenum precursor exposure portion includes a flow of MoO₂Cl₂ and H₂ and a pulsed low-power RF plasma having a pulsed RF power of 50 W or less, a frequency in the range of 100 Hz to 500 Hz and a duty cycle of 25% or less. The reducing agent exposure portion includes a flow of H₂ and a high-power plasma having a continuous RF power of 400 W or higher and substantially no molybdenum precursor co-flow.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a flow process diagram of a metal deposition method according to some embodiments of the present disclosure;

FIG. 2 illustrates a schematic cross-sectional view of a substrate processing system according to some embodiments of the present disclosure;

FIG. 3A illustrates a cross-sectional view of a substrate having a feature before processing according to some embodiments of the present disclosure; and

FIG. 3B illustrates a cross-sectional view of a substrate having a feature after processing according to some embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

As used herein, the term “substrate surface” refers to any substrate surface upon which a layer may be formed. The substrate surface may have one or more features formed therein, one or more layers formed thereon, and combinations thereof. The shape of the feature can be any suitable shape including, but not limited to, peaks, trenches, and cylindrical vias. As used in this regard, the term “feature” refers to any intentional surface irregularity. Suitable examples of features include but are not limited to trenches which have a top, two sidewalls and a bottom, peaks which have a top and two sidewalls extending upward from a surface, and vias which have sidewalls extending down from a surface with a bottom. In some embodiments, the bottom of a via comprises an open bottom defined or bounded by underlying material, for example, dielectric material, which may also define the two sidewalls, or the underlying material at the bottom may be a conductor such as a metal (e.g., copper), which can be the same as or different from the sidewall material.

As used in this specification and the appended claims, the term “selectively” refers to process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

Embodiments of the present disclosure are directed to gapfill methods. In some embodiments, the methods comprise exposing a substrate surface having at least one feature thereon to one or more deposition cycles in order to fill the at least one feature (or gap) and achieve a high throughput of the gapfill process.

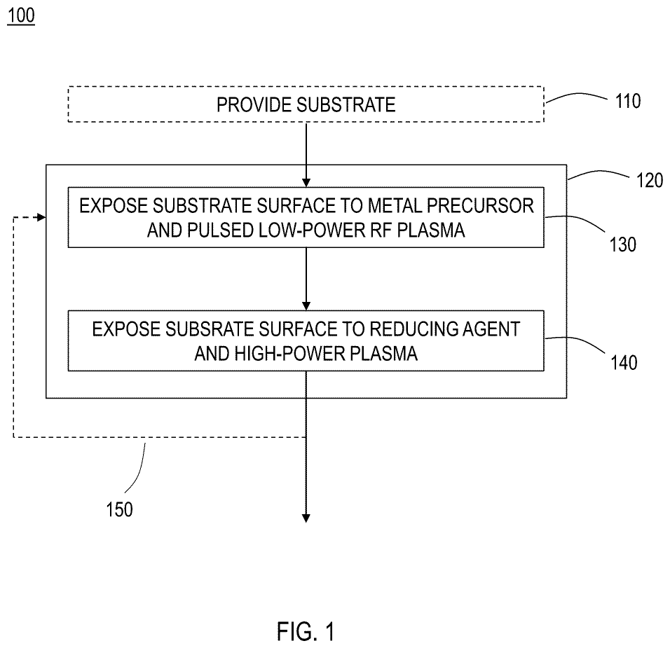

FIG. 1 illustrates a flow process diagram of a method 100 according to some embodiments of the present disclosure. Referring to FIG. 1, at operation 110 of method 100, in some embodiments, a substrate is optionally provided to the processing chamber. As used in this regard, the term “provided” means that the substrate is made available for processing (e.g., positioned in a processing chamber). As used herein, the term “processing chamber” also includes portions of a processing chamber adjacent to the substrate surface without encompassing the complete interior volume of the processing chamber.

In some embodiments, the method 100 includes performing a deposition cycle 120. In the illustrated embodiment, the deposition cycle 120 includes a metal precursor exposure portion 120 and a reducing agent exposure portion 140. The metal precursor exposure portion 120 comprises exposing the substrate surface to a metal precursor and a pulsed low-power RF plasma. The reducing agent exposure portion 140 comprises exposing the substrate surface to a reducing agent and a high-power plasma.

In some embodiments, the metal precursor of the metal precursor exposure portion 120 may comprise any metal suitable for depositing on a semiconductor substrate. Suitable metals include, but are not limited to, molybdenum (Mo), tungsten (W), ruthenium (Ru), or copper (Cu). In some embodiments, the metal precursor is an oxide, nitride, sulfide, or halide of the metal. In some embodiments, the metal precursor is an organometallic species. In some embodiments, the metal film deposited is a molybdenum film. In some embodiments, the molybdenum precursor comprises an oxide, sulfide, nitride, or halide of molybdenum. In some embodiments, the molybdenum precursor comprises one or more of MoO₂Cl₂ or MoCl₅. In some embodiments, the molybdenum precursor consists essentially of one or more of MoO₂Cl₂ or MoCl₅. As used in this manner, the term “consists essentially of” means that the reactive composition of the relevant component or composition is greater than or equal to 95%, 98%, 99% or 99.5% of the stated species. Diluent, carrier and inert gases are not included in the consisting essentially of language. In some embodiments, the molybdenum precursor is an organometallic species comprising one or more molybdenum ions or atoms.

In some embodiments, during the metal precursor exposure portion 120 of deposition cycle 120, the substrate surface is exposed to the metal precursor by flowing the metal precursor into the processing chamber. The metal precursor may be introduced into the processing chamber through various routes, such as through a showerhead electrode or a sidewall injection. In some embodiments, the metal precursor is diluted with an inert gas, such as argon (Ar), nitrogen (N₂), or helium (He).

In some embodiments, the substrate comprises a metal film with a metal surface and a dielectric film with a dielectric surface. In some embodiments, the metal precursor deposits a metal film directly on a dielectric surface of the substrate selectively over one or more metal surfaces of the substrate. For example, the metal film may be a molybdenum film that is deposited directly on a dielectric surface of the substrate such that little or no molybdenum is deposited on one or more metal surfaces of the substrate. In some embodiments, the metal film comprises molybdenum and deposits on silicon oxide, silicon nitride and metal films.

In some embodiments, the metal precursor exposure portion 120 also comprises a pulsed low-power RF plasma. As used in this specification and the appended claims, a “pulsed low-power RF plasma” has an RF power of less than or equal to 100 W. In some embodiments, the pulsed low-power RF plasma has a pulsed RF power of 90 W or less, or 80 W or less, or 70 W or less, or 60 W or less, or 50 W or less, or 40 W or less.

In some embodiments, the pulsed low-power RF plasma used during the metal precursor exposure portion 120 of deposition cycle 120 has a frequency, or pulse frequency, in a range of from 25 Hz to 250 Hz. In some embodiments, the pulse frequency of the pulsed low-power RF plasma is 40 Hz, 50 Hz, 60 Hz, 70 Hz, 80 Hz, 90 Hz, 100 Hz, 125 Hz, 150 Hz, 175 Hz or 200 Hz. In some embodiments, the pulse frequency of the pulsed low-power RF plasma is less than or equal to 200 Hz, 175 Hz, 150 Hz, 125 Hz, 100 Hz, 75 Hz, or 50 Hz.

In some embodiments, the pulsed low-power RF plasma has a duty cycle. As used in this regard, the term “duty cycle” refers to the percentage of time that the pulsed low-power RF plasma is on. In some embodiments, the duty cycle is in a range from 10-90%. For example, the duty cycle may be 10% on or less, 20% on or less, 30% on or less, 40% on or less, 50% on or less, 60% on or less, 70% on or less, 80% on or less, or 90% on or less. In some embodiments, the duty cycle of the pulsed low-power RF plasma is 10%, 20%, 30%, 40% or 50%. In some embodiments, the pulsed low-power RF plasma is in the range of 5% to 50%, or in the range of 10% to 40%.

In some embodiments, the metal precursor exposure portion 120 comprises a pulsed low-power RF plasma, a flow of metal precursor, a co-flow of reducing agent, and a co-flow of diluent. In some embodiments, the metal precursor exposure portion 120 comprises a pulsed low-power RF plasma, a flow of MoO₂Cl₂, a flow of molecular hydrogen, and a flow of argon.

In some embodiments, the metal precursor exposure portion 120 is conducted for a time of 60 seconds or less. In some embodiments, the metal precursor exposure portion 120 is conducted for 20 seconds or less, or 10 seconds or less, or 5 seconds or less, or 3 seconds or less.

In some embodiments, the deposition cycle 120 includes a reducing agent exposure portion 140 including exposing the substrate surface to a reducing agent and to a high-power plasma. The reducing agent may be any reducing agent suitable for introduction into a processing chamber and for reducing the metal precursor used in the metal precursor exposure portion 120 to a metal film. In some embodiments, the reducing agent is molecular hydrogen (H₂). In some embodiments, the reducing agent is also co-flowed with the metal precursor during the metal precursor exposure portion 120, such as it may be flowed continuously during the deposition cycle 120.

In some embodiments, a purge portion (not shown) occurs between the metal precursor exposure portion 120 and the reducing agent exposure portion 140. In some embodiments, the purge period consists essentially of a flow of inert gas to remove reactive species from the processing environment. In some embodiments, a pulsed low-power RF plasma is maintained during the purge portion. In some embodiments, a low-power RF plasma with a continuous power is used during the purge portion. In some embodiments, a pulsed low-power RF plasma during the purge portion has a duty cycle of about 10%, 20%, 30%, 40%, 50%, 60%, 70%, 80% or 90%.

In some embodiments, the reducing agent exposure portion 140 comprises a high-power plasma. As used in this specification and the appended claims, the term “high-power plasma” refers to a plasma with an RF power of 300 W or higher. For example, the high-power plasma may have an RF power of about 300 W, or an RF power of 400 W or higher, or an RF power of 500 W or higher, or an RF power of 600 W or higher, or an RF power of 750 W or higher. In some embodiments, the high-power plasma is a continuous plasma. As used in this manner, a “continuous plasma” is a plasma with a duty cycle greater than or equal to 90%, 95%, 98%, 99% or 99.5%. In some embodiments, the continuous plasma has a power in a range of from 400 W to 500 W. In some embodiments, the continuous plasma has a power greater than or equal to 400 W and a duty cycle about 100%.

In some embodiments, the high-power plasma has a frequency in the range of from 350 kHz to 60 MHz, or in the range of 500 kHz, or 50 MHZ, or in the range of 2 MHZ, to 40 MHz, or in the range of 13.56 MHz to 60 MHz. In some embodiments, the high-power plasma has a frequency greater than or equal to 350 kHz, 500 KHz, 1 MHz, 2 Mhz, 5 MHz, 13.56 MHz, 20 MHz, 40 MHz or 50 MHz, and less than or equal to 100 MHz, 75 MHz or 60 MHz. In some embodiments, the high-power plasma has a frequency less than 60 MHz and greater than or equal to 350 kHz, 500 KHz, 1 MHZ, 2 MHz or 13.56 MHz.

In some embodiments, both the pulsed low-power RF plasma and the high-power plasma comprise a diluent gas comprising argon, nitrogen, or helium. In some embodiments, the diluent gas may be flowed continuously during the deposition cycle 120.

In some embodiments, the reducing agent exposure portion 140 comprises a high-power plasma, flow of reducing agent, and flow of diluent. In some embodiments, the reducing agent exposure portion comprises a high-power plasma, flow of molecular hydrogen, and flow of argon. In some embodiments, the metal precursor is not flowed during the reducing agent exposure portion 120.

In some embodiments, the reducing agent exposure portion 140 is conducted for a time of 60 seconds or less. In some embodiments, the reducing agent exposure portion 140 is conducted for 20 seconds or less, or 10 seconds or less, or 5 seconds or less, or 3 seconds or less.

In some embodiments, the deposition cycle 120 is repeated until the one or more feature of the substrate surface is completely filled. In some embodiments, the feature comprises a trench and the trench is gapfilled. In some embodiments, the gapfilled feature is substantially free of voids or seams. As used in this regard, the term “substantially free” means that less than or equal to 5%, including less than or equal to 4%, less than or equal to 3%, less than or equal to 2%, less than or equal to 1%, less than or equal to 0.5%, or less than or equal to 0.1% of the total composition of the metal gapfill, on an volumetric basis, comprises voids and/or seams.

In some embodiments, after each deposition cycle 120, there is a determination or decision point 150 of whether the feature has been substantially filled. If substantial filling of the feature has not been accomplished, then another deposition cycle 120 is performed. If substantial filling of the feature has been accomplished, then in some embodiments another deposition cycle 120 is not performed, and other optional operations, including post-processing of the substrate or the metal film, or removing the substrate from the processing chamber, may be performed.

In some embodiments, the repeating of the deposition cycle 120 results in a high quality gapfill, with substantially no voids or seams. The repeating of the deposition cycle 120 may also result in a higher throughput compared to an equivalent method that does not use a pulsed low-power RF plasma during the metal precursor exposure portion 120, including an equivalent method that uses a continuous low-power RF plasma. Without intending to be bound by theory, it is believed that the pulsed low-power RF plasma may react with the metal precursor and/or the reducing agent in the gas-phase to increase the deposition kinetics of the metal on the substrate surface. Specifically, the low RF power may prevent over-deposition on the outside of the trench, while the pulsing frequency may provide periods of time where reactions do not occur, thus allowing reduced metal species to diffuse into the deeper part of the trench to fill potential voids or seams.

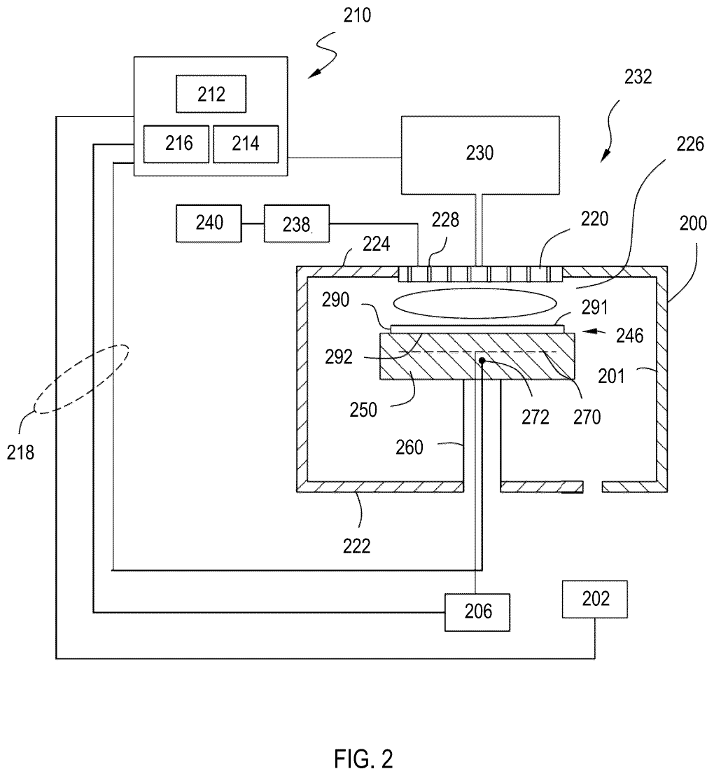

FIG. 2 illustrates a substrate processing system 232 that can be used to perform the gapfill metal deposition (e.g., method 100) in accordance with one or more embodiments described herein. The substrate processing system 232 includes a process chamber 200, coupled to a gas panel 230 and a controller 210. The process chamber 200 generally includes a top wall 224, a sidewall 201, and a bottom wall 222 that together define a processing volume 226. A substrate support assembly 246 is provided in the processing volume 226 of the process chamber 200. The substrate support assembly 246 generally includes an electrostatic chuck 250 supported by a stem 260. The electrostatic chuck 250 may be typically fabricated from aluminum, ceramic, and/or other suitable materials. The electrostatic chuck 250 may be moved in a vertical direction inside the process chamber 200 using a displacement mechanism (not shown).

Referring to FIG. 2, a vacuum pump 202 is coupled to a port formed in the bottom of the process chamber 200. The vacuum pump 202 is used to maintain a desired gas pressure in the process chamber 200. The vacuum pump 202 also evacuates post-processing gases and by-products of the process from the process chamber 200.

The substrate processing system 232 may further include additional equipment for controlling the chamber pressure, for example, valves (e.g., throttle valves and isolation valves) positioned between the process chamber 200 and the vacuum pump 202 to control the chamber pressure.

A gas distribution assembly 220 having a plurality of apertures 228 is disposed on the top of the process chamber 200 above the electrostatic chuck 250. The apertures 228 of the gas distribution assembly 220 are utilized to introduce process gases into the process chamber 200, such as metal precursors, reducing agents, and diluent gases as described herein. The apertures 228 may have different sizes, number, distributions, shape, design, and diameters to facilitate the flow of the various process gases for different process requirements. The gas distribution assembly 220 is connected to the gas panel 230 that allows various gases to supply to the processing volume 226 during processing. A plasma is formed from the process gas mixture exiting the gas distribution assembly 220 to enhance thermal deposition of the process gases resulting in the deposition of metal on a surface 291 of the substrate 290, the substrate 290 resting on an upper surface 292 of the electrostatic chuck 250.

The gas distribution assembly 220 and the electrostatic chuck 250 may form a pair of spaced apart electrodes in the processing volume 226. One or more RF power source 240 provide a bias potential through an optional matching network 238 to the gas distribution assembly 220 to facilitate generation of plasma between the gas distribution assembly 220 and the electrostatic chuck 250. Alternatively, the RF power source 240 and the optional matching network 238 may be coupled to the gas distribution assembly 220, the electrostatic chuck 250, or coupled to both the gas distribution assembly 220 and the electrostatic chuck 250, or coupled to an antenna (not shown) disposed exterior to the process chamber 200. In some embodiments, the RF power source 240 may provide between about 40 W and about 3,000 W at a frequency of about 50 Hz to about 13.6 MHz. In some embodiments, the RF power source 240 may provide between about 400 W and about 500 W at a frequency in a range from 13.56 MHz to 60 MHz.

The controller 210 includes a central processing unit (CPU) 212, a memory 216, and a support circuit 214 utilized to control the process sequence and regulate the gas flows from the gas panel 230. The CPU 212 may be of any form of a general-purpose computer processor that may be used in an industrial setting. The software routines can be stored in the memory 216, such as random access memory, read only memory, floppy, or hard disk drive, or other form of digital storage. The support circuit 214 is conventionally coupled to the CPU 212 and may include cache, clock circuits, input/output systems, power supplies, and the like.

The controller 210, which may be included in any of the described processing apparatus, can have a processor, a memory coupled to the processor, input/output devices coupled to the processor and circuits for communication between the different electronic components. The memory can include any one or more of a transitory memory (e.g., random access memory) and non-transitory memory (e.g., storage).

The memory 216, or computer-readable medium, of the processor may be one or more of readily available memory such as random access memory (RAM), read-only memory (ROM), floppy disk, hard disk, or any other form of digital storage, local or remote. The memory can retain an instruction set that is operable by the processor 212 to control parameters and components of the system. The support circuits 214 are coupled to the processor 212 for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber 200 to perform processes of the present disclosure. The software routine may also be stored and/or executed by a second processor (not shown) that is remotely located from the hardware being controlled by the processor. Some or all of the methods of the present disclosure may also be performed in the hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

Bidirectional communication between the controller 210 and the various components of the substrate processing system 232 are handled through numerous signal cables collectively referred to as signal buses 218, some of which are illustrated in FIG. 2.

Referring to FIG. 2, a temperature sensor 272, such as a thermocouple, may be embedded in the electrostatic chuck 250 to monitor the temperature of the electrostatic chuck 250 in a conventional manner. The measured temperature is used by the controller 210 to control the power supplied to the heater element 270 by the heater power source 206, in order to maintain the substrate 292 at a desired temperature.

In general, the following exemplary deposition process parameters may be used to form the gapfill within the substrate feature. The substrate temperature may range from about −50° C. to about 500° C. (e.g., from about 250° C. to about 250° C.; or from about 250° C. to about 450° C.). The chamber pressure may range from a chamber pressure of about 0.5 mTorr to about 10 Torr (e.g., about 2 mTorr to about 50 mTorr; or between about 2 mTorr and about 10 mTorr). The flow rate of the gapfill precursor may be from about 10 sccm to about 1,500 sccm (e.g., from about 500 sccm to about 1000 sccm, or from about 1000 sccm to about 1,500 sccm). The flow rate of a dilution gas may individually range from about 50 sccm to about 50,000 sccm (e.g., from about 1000 sccm to about 10,000 sccm). The spacing between the gas distribution assembly and the substrate may be from about 1,000 to about 15,000 mils (e.g., from about 6,000 to about 12,000 mils, or from about 8,000 to about 12,000 mils).

The gapfill may be deposited to a thickness between about 5 Å and about 20,000 Å (e.g., between about 300 Å to about 5000 Å; between about 2000 Å and about 3000 Å, or between about 5 Å to about 200 Å).

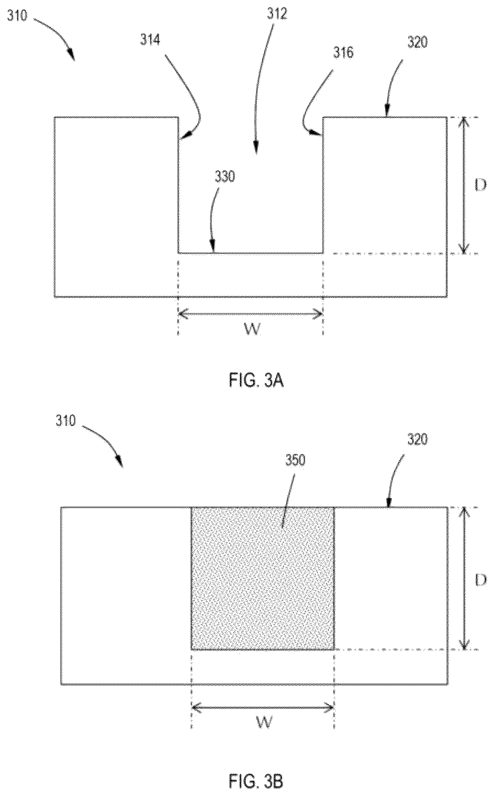

With reference to FIGS. 3A and 3B, in some embodiments, the substrate surface has one or more features 312. FIGS. 3A-3B depict substrates having a single feature 312 for illustrative purposes only; however, the skilled person will understand that there can be more than one feature. The shape of the feature 312 can be any suitable shape, including, but not limited to trenches and cylindrical vias.

FIG. 3A depicts a partial cross-sectional view of a substrate 310 having a feature 312. The substrate 310 has a top surface 320. The feature 312 extends from the top surface 320 a depth D to a bottom surface 330. The feature 312 has a first sidewall 314 and a second sidewall 316 that define an opening width W of the feature 312. The open area defined by the sidewalls and the bottom is also referred to as a gap.

In specific embodiments, the feature 312 is a trench. Features can have any suitable aspect ratio (ratio of the depth D of the feature to the width W of the feature). In some embodiments, the aspect ratio is greater than or equal to about 5:1, 10:1, 15:1, 20:1, 25:1, 20:1, 25:1 or 40:1.

The substrate 310 may be a silicon-based material or any suitable insulating material or conductive material as needed, having a feature 312 disposed on the substrate 310 that may be filled with metal gapfill 350, as illustrated in FIG. 3B.

As shown in the exemplary embodiment depicted in FIG. 3A, the substrate 310 may have a top surface 320 that is substantially planar (as shown), uneven, or substantially planar surface having structures formed thereon or additional features formed therein.

In some embodiments, the substrate 310 may be a material such as crystalline silicon (e.g., Si<100> or Si<111>), silicon oxide, strained silicon, silicon germanium, doped or undoped polysilicon, doped or undoped silicon substrates and patterned or non-patterned substrates silicon on insulator (SOI), carbon doped silicon oxides, silicon nitride, doped silicon, germanium, gallium arsenide, glass, sapphire. The substrate 310 may have various dimensions, such as 200 mm, 300 mm, and 450 mm or other diameter substrates, as well as rectangular or square panels. Unless otherwise noted, embodiments and examples described herein are conducted on substrates with a 200 mm diameter, a 300 mm diameter, or a 450 mm diameter substrate. In the embodiments wherein a SOI structure is utilized for the substrate 310, the substrate 310 may include a buried dielectric layer disposed on a silicon crystalline substrate. In the embodiments depicted herein, the substrate 310 may be a crystalline silicon substrate.

It is noted that the gapfill may be formed on any surfaces or any portion of the substrate 310 inside or outside of the feature 312 present on the substrate 310, including the top surface 320.

In one or more embodiments, the metal gapfill 350 is deposited and there is substantially no seam formed in the gap. The formation of a seam occurs where the thickness of the film closes on the top part of the feature 312 before the feature is filled with the film, “breadloafing”. A seam can be any gap, space or void that forms between the sidewalls 314, 316 of the feature 312.

Further embodiments of the present disclosure are directed to non-transitory computer readable medium including instructions, that, when executed by a controller of a processing chamber, causes the processing chamber to perform operations of: exposing a substrate surface having at least one feature thereon to one or more deposition cycle, each deposition cycle comprising a metal precursor exposure portion and a reducing agent exposure portion, the metal precursor exposure portion including a flow of a metal precursor and a pulsed low-power RF plasma having a pulsed RF power of 100 W or less, the reducing agent exposure portion including a flow of a reducing agent and a high-power plasma having an RF power of 300 W or higher.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A metal deposition method comprising:
exposing a substrate surface having at least one feature thereon to one or more deposition cycle, each deposition cycle comprising a metal precursor exposure portion and a reducing agent exposure portion, the metal precursor exposure portion including a flow of a metal precursor and a pulsed low-power RF plasma having a pulsed RF power of 100 W or less, the reducing agent exposure portion including a flow of a reducing agent and a high-power plasma having an RF power of 300 W or higher.

2. The metal deposition method of claim 1, further comprising repeating the deposition cycle to fill the at least one feature.

3. The metal deposition method of claim 1, wherein the metal precursor exposure portion further comprises a co-flow of the reducing agent.

4. The metal deposition method of claim 1, wherein the pulsed low-power RF plasma of the metal precursor exposure portion has a pulsed RF power of 50 W or less.

5. The metal deposition method of claim 1, wherein the pulsed low-power RF plasma of the metal precursor exposure portion has a duty cycle in the range of 10-90%.

6. The metal deposition method of claim 1, wherein the pulsed low-power RF plasma of the metal precursor exposure portion has a frequency in the range of 50 Hz to 1000 Hz.

7. The metal deposition method of claim 1, wherein the metal precursor comprises MoO₂Cl₂ or MoCl₅.

8. The metal deposition method of claim 1, wherein the reducing agent comprises molecular hydrogen.

9. The metal deposition method of claim 8, wherein the high-power plasma is a continuous plasma.

10. The metal deposition method of claim 9, wherein the continuous plasma has a power in the range of 400 W to 500 W.

11. The metal deposition method of claim 1, wherein the pulsed low-power RF plasma and the high-power plasma comprise a diluent gas comprising argon, nitrogen, or helium.

12. The metal deposition method of claim 1, wherein the high-power plasma has a frequency in the range of 13.56 MHz to 60 MHz.

13. A molybdenum deposition method comprising:
performing a deposition cycle on a semiconductor substrate surface, each deposition cycle comprising:
exposing the semiconductor substrate surface to a molybdenum precursor and a pulsed low-power RF plasma to form a molybdenum film on the semiconductor substrate surface, the pulsed low-power RF plasma having an RF power of 100 W or less and a pulse frequency of from 50 Hz to 500 Hz, and
exposing the semiconductor substrate surface to a high-power plasma in the absence of the molybdenum precursor, the high-power plasma having a power of 300 W or greater; and
repeating the deposition cycle until the molybdenum film completely fills one or more features on the semiconductor substrate surface.

14. The molybdenum deposition method of claim 13, wherein the pulsed low-power RF plasma and the high-power plasma comprise a diluent gas comprising argon, nitrogen, or helium.

15. The molybdenum deposition method of claim 13, wherein the deposition cycle comprises a continuous flow of hydrogen during both the pulsed low-power RF plasma and the high-power plasma.

16. The molybdenum deposition method of claim 13, wherein the high-power plasma has a frequency in the range of 13.56 MHz to 60 MHz.

17. The molybdenum deposition method of claim 13, wherein the high-power plasma is a continuous plasma.

18. The molybdenum deposition method of claim 13, wherein the pulsed low-power RF plasma has a duty cycle of 20% or less.

19. The molybdenum deposition method of claim 13, wherein the molybdenum precursor comprises MoO₂Cl₂ or MoCl₅.

20. A molybdenum deposition method comprising:
exposing a substrate surface having at least one feature thereon to one or more deposition cycle, each deposition cycle comprising a molybdenum precursor exposure portion and a reducing agent exposure portion, the molybdenum precursor exposure portion comprising:
a flow of MoO₂Cl₂ and H₂ and a pulsed low-power RF plasma having a pulsed RF power of 50 W or less, a frequency in the range of 100 Hz to 500 Hz and a duty cycle of 25% or less, and
the reducing agent exposure portion comprising:
a flow of H₂ and a high-power plasma having a continuous RF power of 400 W or higher and substantially no molybdenum precursor co-flow.
